(19) United States
(12) Patent Application Publication
(10) Pub. No.: US 2015/0259256 A1
(43) Pub. Date: Sep. 17, 2015

(54) CERAMIC COMPONENT HAVING PROTECTIVE LAYER AND METHOD OF PRODUCTION THEREOF

(71) Applicant: EPCOS AG, München (DE)

(72) Inventors: Peter Urdl, Stainz (AT); Gerald Kloiber, Feldkirchen (AT); Lutz Kirsten, Deutschlandsberg (AT)

(21) Appl. No.: 14/433,865

(22) PCT Filed: Aug. 16, 2013
(86) PCT No.: PCT/EP2013/067165

§ 371 Date: Apr. 7, 2015

(30) Foreign Application Priority Data
Oct. 11, 2012 (DE) 10 2012 109 704.6

(51) Int. Cl. C04B 41/48; C04B 41/88; C23C 16/50; C04B 41/52; C04B 41/51; C23C 16/44; C04B 41/00; C04B 41/83

(52) U.S. Cl. CPC C04B 41/4853; C04B 41/009; C04B 41/88; C04B 41/83; C04B 41/522; C04B 41/5116; C23C 16/44; C23C 16/50

(57) ABSTRACT

A ceramic component includes a ceramic main body having at least one metallization on at least one exterior surface of the main body and at least one electric inlet lead in electrical contact with the metallization, and an inner protective layer and an outer protective layer that encapsulates the component, wherein the inner protective layer includes at least one material selected from the group consisting of phosphonates (SAMP), silanes, Parylenes and combinations thereof, and the inner protective layer a) contains at least first functional groups via which covalent chemical bonding to at least the ceramic main body is effected and/or b) has been deposited by chemical vapor deposition.

### TECHNICAL FIELD

This disclosure relates to ceramic components having protective layers and methods of producing such components.

### BACKGROUND

Electroceramic components used as resistance elements in electronics are known. Specifically, electroceramic components having variable resistance properties are known, for example, voltage-dependent resistors and temperature-dependent resistors. Temperature-dependent resistors encompass cold conductors or PTC resistors (PTC=positive temperature coefficient), whose ceramics conduct the current better at low temperatures than at high temperatures, and hot conductors or NTC resistors (NTC=negative temperature coefficient), whose ceramics are characterized by an increasing electrical conductivity as the temperature is increased. Such electroceramic components are employed, for example, as protective components, switching elements or sensor elements. Hot conductors are used as, inter alia, temperature sensors, for example, in resistance thermometers. In particular, hot conductors are used as engine temperature sensors in motor vehicles.

In conventional ceramic components, a change in the specific electrical parameters, in particular an increase in the specific resistance, or even a loss of function is frequently observed under use conditions as the time of use increases. This applies, for example, to the use of NTC resistors as temperature sensors in automotive applications. This lack of stability and reliability of conventional ceramic components is a known problem.

It could therefore be helpful to provide ceramic components which display improved stability and reliability in respect of their specific electrical parameters under use conditions.

### SUMMARY

We provide a ceramic component including a ceramic main body having at least one metallization on at least one exterior surface of the main body and at least one electric inlet lead in electrical contact with the metallization, and an inner protective layer and an outer protective layer that encapsulates the component, wherein the inner protective layer includes at least one material selected from the group consisting of phosphonates (SAMP), silanes, Parylenes and combinations thereof, and the inner protective layer a) contains at least first functional groups via which covalent chemical bonding to at least the ceramic main body is effected and/or b) has been deposited by chemical vapor deposition.

We also provide a method of producing the ceramic component including A) providing the ceramic main body having the metallization on at least one exterior surface of the main body and the electric inlet lead in electrical contact with the metallization, B) producing the inner protective layer, and C) producing the outer protective layer on top of the inner protective layer.

### BRIEF DESCRIPTION OF THE DRAWINGS

FIGS. 1A to 1C show a ceramic component configured as NTC minisensor in various stages of production by schematic cross sections.

FIG. 2 shows a further example of the ceramic component of FIG. 1 with intermediate layer between inner and outer protective layer.

FIGS. 3A to 3C show further examples of the ceramic component of FIG. 1 with additional arrangement of further protective layers outside on the outer protective layer.

FIG. 4A shows the change in resistance of an NTC minisensor having an inner protective layer composed of phosphonates in the water storage test compared to a conventional NTC minisensor.

FIG. 4B shows the change in resistance of a further NTC minisensor having an inner protective layer composed of Parylenes in the water storage test compared to a conventional NTC minisensor.

### LIST OF REFERENCE SYMBOLS

CB ceramic main body
EM metallization
OF exterior surface
EC electric inlet lead
IL inner protective layer
EL outer protective layer
SL intermediate layer
SJ solder connection
OC1 first further protective layer
OC2 second further protective layer
OC3 third further protective layer

### DETAILED DESCRIPTION

We provide a ceramic component having a ceramic main body which can, for example, be an electroceramic. For example, the ceramic main body can comprise electroceramics which have a variable resistance, for example, a voltage-dependent resistor (varistors) or a temperature-dependent resistor. In particular, ceramics having a positive temperature coefficient (PTC resistors) or ceramics having a negative temperature coefficient (NTC resistors) are provided. In particular examples, ceramics which have a negative temperature coefficient, i.e., are hot conductors, are provided.

At least one metallization is arranged on at least one exterior surface of the ceramic main body. This metallization can, for example, be provided as a contact layer. A metallization configured as contact layer can, for example, be electrically connected to one or more electrode layers arranged in the main body.

At least one electric inlet lead which establishes electrical contact with the metallization is provided. For example, the electric inlet lead can be electrically connected to the metallization by a solder connection. The electric inlet lead makes it possible, for example, to integrate the ceramic component into an electric circuit arrangement.

To encapsulate the component, an inner protective layer and an outer protective layer are provided. The inner protective layer can contain at least first functional groups via which the inner protective layer is chemically covalently bound to at least the ceramic main body. In particular examples, the inner protective layer is, for example, arranged in a covalently bound manner as specifically oriented monomolecular layer (self assembled monolayer, SAM). The inner protective layer preferably has hydrophobic properties. Furthermore, the inner protective layer preferably has oleophobic properties. Particular preference is given to an inner protective layer which has both hydrophobic properties and oleophobic properties. Due to the chemical covalent bonding, the inner protective layer and the ceramic substrate are joined to one another particularly firmly and form a good seal to one another. Owing to these properties, good protection against crack formation in the inner protective layer in temperature change stress is also present.

As an alternative to chemical covalent bonding, the inner protective layer can have been deposited by chemical vapor deposition (CVD). For example, the inner protective layer deposited by CVD has a high conformity, i.e., a largely homogeneous layer thickness on horizontal and vertical surfaces of the component. The inner protective layer deposited by CVD is preferably pore-free and specially pinhole-free. The inner protective layer is preferably hydrophobic. The inner protective layer also preferably has a very good barrier action against organic media. In particular, the inner protective layer is hydrophobic and at the same time has a very good barrier action against organic media and also against water vapor and further gaseous media.

In a further example, the inner protective layer both contains first functional groups and has been deposited by CVD so that the properties of the covalent chemical bonding of the inner protective layer to the ceramic main body are combined particularly advantageously with the properties of an inner protective layer deposited by CVD.

We established that contact of a ceramic component with ambient media, for example, water, can be the main cause of a change in the specific electrical parameters of ceramic components. In particular, we established that in automotive applications of ceramic components, water or water vapor, exhaust gas condensates and/or engine oils penetrate as far as the ceramic substrate and can bring about resistance changes there. In particular, we also established that conventional protective layers of ceramic components tend to form cracks under temperature change stress, as a result of which protection of the ceramic substrate can additionally be impaired before penetration of surrounding media. As a result of the combination of the inner and outer protective layers, the component is encapsulated in a particularly resistant manner against penetration of surrounding media and thus ensures particularly good protection of the ceramic. The ceramic components therefore display improved stability and reliability with respect to their specific electrical parameters under use conditions.

The ceramic main body can, for example, be configured as a monolithic ceramic main body. As a further variant, it is possible for the main body to be configured as a stack of ceramic layers. Furthermore, one or more electrically conductive electrode layers can be present in the interior of the ceramic main body. In particular examples, a plurality of parallel electrode layers are arranged in the form of electrode bundles. Different electrodes can be horizontally and/or vertically opposite one another with respect to the layer planes in the main body. In particular, the electrical properties of the component are determined by the ceramic main body and any electrode layers present.

The metallization can, for example, comprise aluminum, silver or copper or be an alloy comprising aluminum, silver or copper. It is possible for at least two metallizations which are, for example, arranged on opposite exterior surfaces of the ceramic main body to be provided. In addition, two electric inlet leads can be provided to establish separate electrical contact between each of the two metallizations and one of these electric inlet leads and thus allow integration of the ceramic component into an electric circuit arrangement.

Preferably, the inner protective layer is arranged on the ceramic main body, the metallization and at least the part of the electric inlet lead adjoining the metallization. Furthermore, a solder connection can be provided between the metallization and the electric inlet lead and the inner protective layer is similarly arranged on this. It is also possible for a plurality of these features to be combined in the ceramic component. For example, a plurality of metallizations and a plurality of electric inlet leads on which the inner protective layer is arranged in each case can be provided in the component. The inner protective layer is preferably additionally chemically covalently bound via the first functional groups to the metallization and the electric inlet lead and also, optionally, to the solder connection. As a result of this configuration of the inner protective layer, the transition regions, in particular, of the ceramic main body to the metallization and of the metallization to the electric inlet lead or to the solder connection are well protected against entry of ambient media. In further examples, the electric inlet lead is enveloped by an insulating material at least in the region adjoining the metallization or the solder connection. For example, the insulating material can comprise a thermoplastic, for example, a polyether ether ketone (PEEK). For example, the electric inlet lead can be insulated by a PEEK insulation tube.

In a further example, an intermediate layer is arranged between the inner protective layer and the outer protective layer. For example, the inner protective layer can be provided as bonding layer for the intermediate layer so that improved bonding of the intermediate layer to the ceramic component is ensured in this way. The intermediate layer can, for example, be provided to further reinforce the barrier action of inner and outer protective layers against the surrounding media.

It is possible for the inner protective layer to additionally contain second functional groups via which covalent chemical bonding to the outer protective layer is effected. Covalent chemical bonding of the inner protective layer to the intermediate layer can also be effected via the second functional groups. In addition, particular examples provide for the inner protective layer to be in contact both with the intermediate layer and with the outer protective layer and to be chemically covalently bound to these via the second functional groups. In this way, firm bonding of the outer protective layer and/or, if present, the intermediate layer to the ceramic component via the first and second functional groups of the inner protective layer is achieved, by which particularly well sealing and stable encapsulation having a particularly good barrier action against penetration of ambient media is realized.

In a further example, the intermediate layer contains third functional groups via which covalent chemical bonding to the outer protective layer is effected. In this way, very good adhesion and a mutually well sealing bond between the outer protective layer and the intermediate layer is achieved.

Possible materials for the inner protective layer are, for example, materials selected from the group consisting of phosphonates, in particular specifically oriented monomolecular phosphonate layers having a P—O-metal bond (self-assembled monolayer of phosphonates, SAMP), silanes, silicates and Parylenes. Furthermore, the inner protective layer can consist of combinations of these materials. An inner protective layer composed of phosphonates or silanes displays strong, chemical covalent bonding to the ceramic main body and optionally to the metallization and at least the part of the electric inlet lead adjoining the metallization. The inner protective layer can, for example, be a monomolecular layer but can also have a multilayer structure, for example, in inner protective layers composed of polyvalent silane compounds. The organic radicals of the phosphonates and silane compounds can comprise functional groups which, for example, have hydrophobic and/or oleophobic properties or serve to covalently chemically bond the inner protective layer to the outer protective layer or the intermediate layer. The strong covalent chemical bonding of these materials to the substrate prevents ambient media from getting between the layers or between the layers and the main body and in this way getting to the surface of the substrate.

Inner protective layers composed of silicates can have covalent chemical bonding to the ceramic main body and optionally to the metallization and at least the part of the electric contacting adjoining the metallization. Inner protective layers composed of silicates are preferably provided as bonding layer in combination with an intermediate layer arranged thereon Inner protective layers composed of silicates can have a high surface energy, by which advantageous uniform wetting with the intermediate layer arranged thereon can be achieved. Furthermore, it is advantageous that inner protective layers composed of silicates can be made very thin while at the same time having a very high molecule density.

Parylenes are thermoplastic polymers having xylene groups linked in the para position. The xylene groups can be substituted in the other positions, for example, by functional groups to effect covalent chemical bonding of the Parylenes or to control the barrier action against ambient media. Protective layers composed of Parylenes are, for example, very homogeneous, micropore- and pinhole-free, free of stresses, hydrophobic and have a very good barrier action against organic media, acids, bases and water vapor. Preferably, the coefficient of thermal expansion of an inner protective layer consisting of Parylenes is comparable to that of the constituents of the ceramic component. In this way, crack formation in a protective layer composed of Parylenes as a result of temperature change stress is prevented.

Possible materials for the outer protective layer are, for example, epoxy resins, polyurethanes and silicone elastomers. Furthermore, combinations of these materials can also be provided. Ceramic components whose encapsulation has an outer protective layer composed of these materials display particularly good stability and reliability under use conditions.

In a further example, the intermediate layer comprises Parylenes. An intermediate layer composed of Parylenes is, for example, very homogeneous, pinhole-free, free of stresses, hydrophobic and has a very good barrier action against organic media, acids, bases and water vapor.

In further examples, further protective layers are arranged on the outer protective layer. For example, a first further protective layer can be arranged outside on the outer protective layer with chemical covalent bonding to the outer protective layer via fourth functional groups being present and/or with the first further protective layer having been deposited by chemical vapor deposition. Furthermore, a second further protective layer can also be arranged outside on the first further protective layer. As second further protective layer, it is possible to provide, for example, a layer having the properties of the outer protective layer. In a further example, a further intermediate layer can also be arranged between the first further protective layer and the second further protective layer. The first further protective layer can be chemically covalently bound via fifth functional groups to the intermediate layer and/or the second further protective layer. Furthermore, the further intermediate layer can be chemically covalently bound via sixth functional groups to the second further protective layer. These examples provide a ceramic component particularly effectively encapsulated against entry of surrounding media. In further examples, arrangement of the protective layers additionally comprises further protective layers.

The ceramic component may be configured as an NTC resistor. Such NTC resistors are particularly suitable for use in, for example, a water vapor and exhaust gas atmosphere since the encapsulation particularly effectively avoids penetration of moisture and/or organic media to the ceramic main body.

We further provide a method of producing the ceramic component having the abovementioned features. The method comprises the steps A) provision of the ceramic main body having the metallization on at least one exterior surface of the main body and the electric inlet lead in electrical contact with the metallization, B) production of the inner protective layer and C) production of the outer protective layer on top of the inner protective layer.

In a further example of the method, the intermediate layer is produced on the inner protective layer in a further step B2) carried out after the step B) and before step C).

The production of the inner protective layer in step B) can, for example, be carried out by contacting the substrate with a solution comprising the material of which the inner protective layer is made. As an alternative, the material of which the inner protective layer is made can also be deposited by physical vapor deposition (PVD). As a starting material to produce the inner protective layer by contacting the substrate with a solution, it is possible to use, for example, materials selected from the group consisting of phosphonic acids, in particular SAMP-OH, and silanes in alcoholic solution. For example, inner protective layers composed of silanes or phosphonates (SAMP) can be produced in this way. Gaseous silanes, for example, are possibilities to produce the inner protective layer by PVD. In particular examples, the inner protective layer is produced by chemical vapor deposition (CVD) in step B). CVD makes it possible to produce, for example, ceramic components whose inner protective layers have particularly high conformity. For example, we provide for an inner protective layer composed of Parylenes to be produced by chemical vapor deposition. In further examples, an inner protective layer composed of silicates is produced by chemical vapor deposition, for example, by flame-pyrolytic coating (CCVD). To produce an inner protective layer composed of silicates, it is possible to use, for example, silicon compounds as precursors.

In a further example, the intermediate layer is produced by chemical vapor deposition in step B2). For example, an intermediate layer of Parylenes can be produced by chemical vapor deposition. Production of intermediate layers composed of silicates or silanes by chemical vapor deposition is also possible.

Production of the outer protective layer in step C) can, for example, be carried out by contacting the substrate with a solution comprising the material of which the outer protective layer is made. It is possible, for example, to contact the substrate in dipping processes, optionally with subsequent removal of excess material.

In one example, a plasma treatment is carried out in a further step B3) before the step C). For example, step B3) can be carried out after step B) so that plasma treatment of the inner protective layer is effected. As an alternative, step B3) can also take place after step B2) so that plasma treatment of the intermediate layer is effected. The plasma treatment makes it possible to produce functional groups in a targeted manner on the surface of the treated layer. Covalent chemical bonding to the layer located on top can, for example, be achieved via these. In particular, the use of, for example, oxygen, nitrogen or ammonia gases in the plasma treatment enables O- or N-functional groups to be produced on the surface of the treated layer. For example, the second functional groups of the inner protective layer or the third functional groups of the intermediate layer can be produced by the plasma treatment in step B3).

In a further example, a plasma treatment is likewise carried out in an additional step C2) after the step C). For example, a plasma treatment on the outer protective layer can be carried out to produce functional groups on the surface of the layer. These can, for example, allow covalent chemical bonding of the outer protective layer to a further protective layer arranged on top.

Further process steps after step C), in which further protective layers are produced outside on the outer protective layer, are possible.

Possibilities for first functional groups are, for example, —O-functional groups. The first functional groups can, for example, be produced by a substitution or condensation reaction of —OH, —Cl or —OR functional groups. For example, silanes can comprise Si—O—R groups reacted by condensation and elimination of water to form an Si—O bond to the ceramic main body or to the metallization and the electric inlet lead. Correspondingly, P—OH groups of phosphonic acids can be reacted by condensation and elimination of water to form a P—O bond to the ceramic main body or to the metallization and the electric inlet lead.

The second functional groups can, for example, be produced from amino, hydroxyl, epoxy, alkyl or vinyl groups. The second functional groups can also comprise halogenated alkyl groups, for example, fluorinated alkyl groups.

Examples of the ceramic component are configurations having
an inner protective layer composed of silane and an outer protective layer composed of epoxy resin;
an inner protective layer composed of silane and an outer protective layer composed of polyurethane;
an inner protective layer composed of silane and an outer protective layer composed of silicone elastomer;
an inner protective layer composed of phosphonates and an outer protective layer composed of epoxy resin;
an inner protective layer composed of phosphonates and an outer protective layer composed of polyurethane;
an inner protective layer composed of phosphonates and an outer protective layer composed of silicone elastomer;
an inner protective layer composed of Parylenes and an outer protective layer composed of epoxy resin;
an inner protective layer composed of Parylenes and an outer protective layer composed of polyurethane;
an inner protective layer composed of Parylenes and an outer protective layer composed of silicone elastomer.

Further possible configurations have
an inner protective layer composed of silicate, an intermediate layer composed of silane and an outer protective layer composed of epoxy resin;
an inner protective layer composed of silicate, an intermediate layer composed of silane and an outer protective layer composed of polyurethane;
an inner protective layer composed of silicate, an intermediate layer composed of silane and an outer protective layer composed of silicone elastomer;
an inner protective layer composed of silicate, an intermediate layer composed of phosphonates and an outer protective layer composed of epoxy resin;
an inner protective layer composed of silicate, an intermediate layer composed of phosphonates and an outer protective layer composed of polyurethane;
an inner protective layer composed of silicate, an intermediate layer composed of phosphonates and an outer protective layer composed of silicone elastomer;
   and also
an inner protective layer composed of silicate, an intermediate layer composed of Parylenes and an outer protective layer composed of epoxy resin;
an inner protective layer composed of silicate, an intermediate layer composed of Parylenes, an outer protective layer composed of polyurethane;
an inner protective layer composed of silicate, an intermediate layer composed of Parylenes and an outer protective layer composed of silicone elastomer.

Ceramic components having
an inner protective layer composed of silane, an intermediate layer composed of Parylenes and an outer protective layer composed of epoxy resin;
an inner protective layer composed of silane, an intermediate layer composed of Parylenes and an outer protective layer composed of polyurethane;
an inner protective layer composed of silane, an intermediate layer composed of Parylenes and an outer protective layer composed of silicone elastomer
   are likewise possible.

Furthermore, the component encompasses configurations of the abovementioned ceramic components having at least one further protective layer arranged on the outer protective layer. In particular, the abovementioned examples having a further phosphonate or silane layer on top of the outer protective layer or a further Parylene layer on top of the outer protective layer are possible.

In further examples, at least two further protective layers are arranged on top of the outer protective layer in the abovementioned ceramic components. Possible examples are arrangements outside on the outer protective layer having
a first further protective layer composed of silicate and a second further protective layer arranged thereon composed of Parylenes;
a first further protective layer composed of silicate and a second further protective layer arranged thereon composed of phosphonates;
a first further protective layer composed of silicate and a second further protective layer arranged thereon composed of silane;
a first further protective layer composed of Parylenes and a second further protective layer arranged thereon composed of epoxy resin;
a first further protective layer composed of Parylenes and a second further protective layer arranged thereon composed of polyurethane;
a first further protective layer composed of Parylenes and a second further protective layer arranged thereon composed of silicone elastomer;
a first further protective layer composed of phosphonates and a second further protective layer arranged thereon composed of epoxy resin;
a first further protective layer composed of phosphonates and a second further protective layer arranged thereon composed of polyurethane;
a first further protective layer composed of phosphonates and a second further protective layer arranged thereon composed of silicone elastomer.

In further examples of the abovementioned ceramic components, at least three further protective layers are arranged on top of the outer protective layer. Possible examples are arrangements on the outer protective layer having
a first further protective layer composed of silicate, a second further protective layer arranged thereon composed of Parylenes and a third further protective layer arranged thereon composed of epoxy resin;
a first further protective layer composed of silicate, a second further protective layer arranged thereon composed of Parylenes and a third further protective layer arranged thereon composed of polyurethane;
a first further protective layer composed of silicate, a second further protective layer arranged thereon composed of Parylenes and a third further protective layer arranged thereon composed of silicone elastomer;
a first further protective layer composed of silicate, a second further protective layer arranged thereon composed of phosphonates and a third further protective layer arranged thereon composed of epoxy resin;
a first further protective layer composed of silicate, a second further protective layer arranged thereon composed of phosphonates and a third further protective layer arranged thereon composed of polyurethane;
a first further protective layer composed of silicate, a second further protective layer arranged thereon composed of phosphonates and a third further protective layer arranged thereon composed of silicone elastomer;
a first further protective layer composed of silicate, a second further protective layer arranged thereon composed of silane and a third further protective layer arranged thereon composed of epoxy resin;
a first further protective layer composed of silicate, a second further protective layer arranged thereon composed of silane and a third further protective layer arranged thereon composed of polyurethane;
a first further protective layer composed of silicate, a second further protective layer arranged thereon composed of silane and a third further protective layer arranged thereon composed of silicone elastomer.

The ceramic component will be illustrated below with the aid of figures and examples. The figures and examples do not imply a limitation to specific details. Individual features can be provided with reference symbols for purposes of illustration, but the presence of a plurality of these features is not ruled out. In addition, the features depicted in the figures for the purposes of illustration are not necessarily shown true to scale.

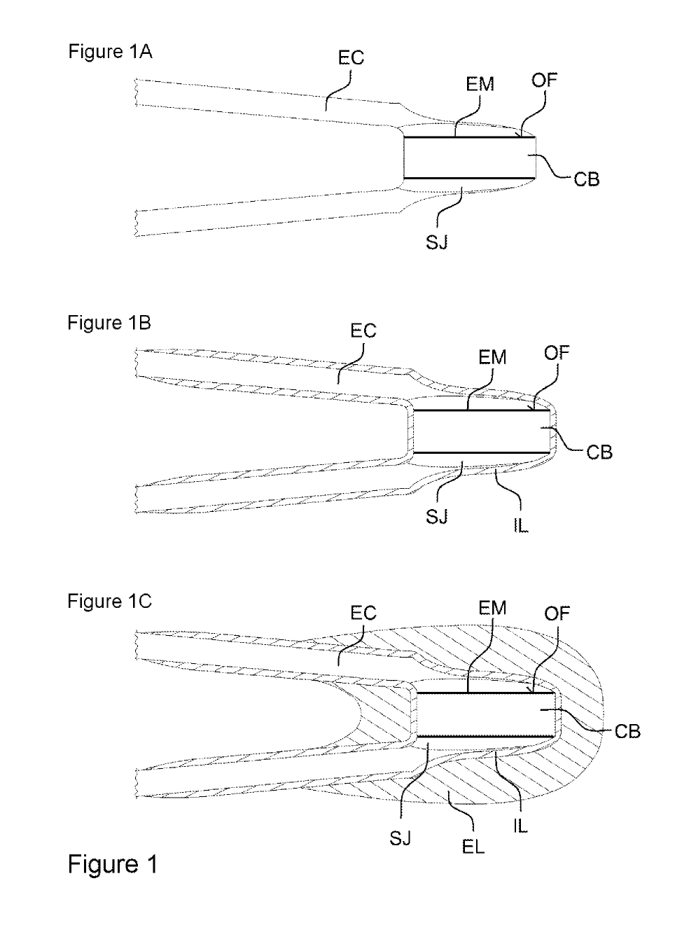

FIG. 1A shows a plan view of a ceramic component configured as NTC minisensor having a ceramic main body (CB), two metallizations (EM) arranged on opposite exterior surfaces (OF) of the main body and also two electric inlet leads (EC) which are each in electrical contact with one of the metallizations. The electric inlet leads are joined to the metallizations by a solder connection (SJ).

FIG. 1B shows the component after production of the inner protective layer (IL) on the ceramic main body (CB), the metallizations (EM) and also the solder connection (SJ) and the part of the electric inlet leads (EC) adjoining the metallizations in sectional view through the inner protective layer. FIG. 1C shows the component after production of the outer protective layer (EL) outside on the inner protective layer (IL) in sectional view through the inner and outer protective layer. The outer protective layer has a greater layer thickness than the inner protective layer. It can clearly be seen how the ceramic component is encapsulated by the sequence of inner and outer protective layer.

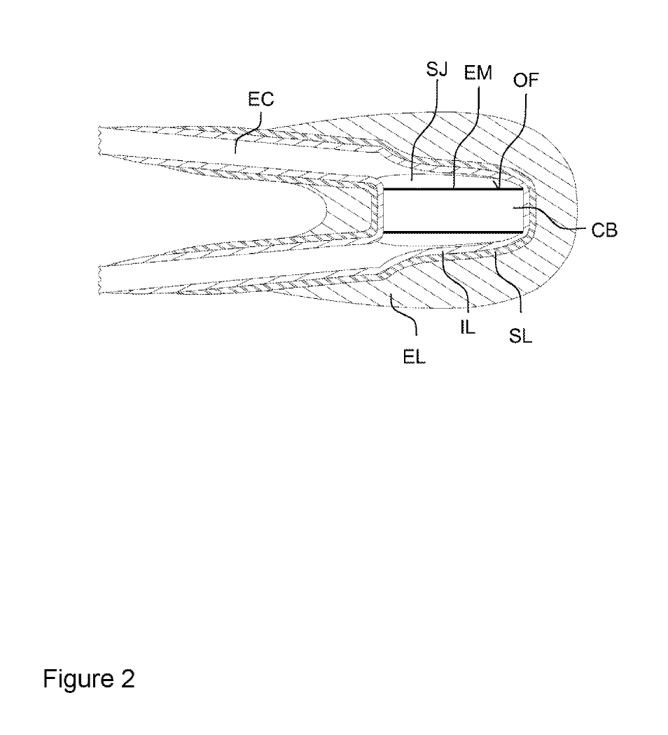

FIG. 2 shows a further example of the component, in which an intermediate layer (SL) is arranged between the inner protective layer (IL) and the outer protective layer (EL). The encapsulation thus consists of three layers which are shown in sectional view here.

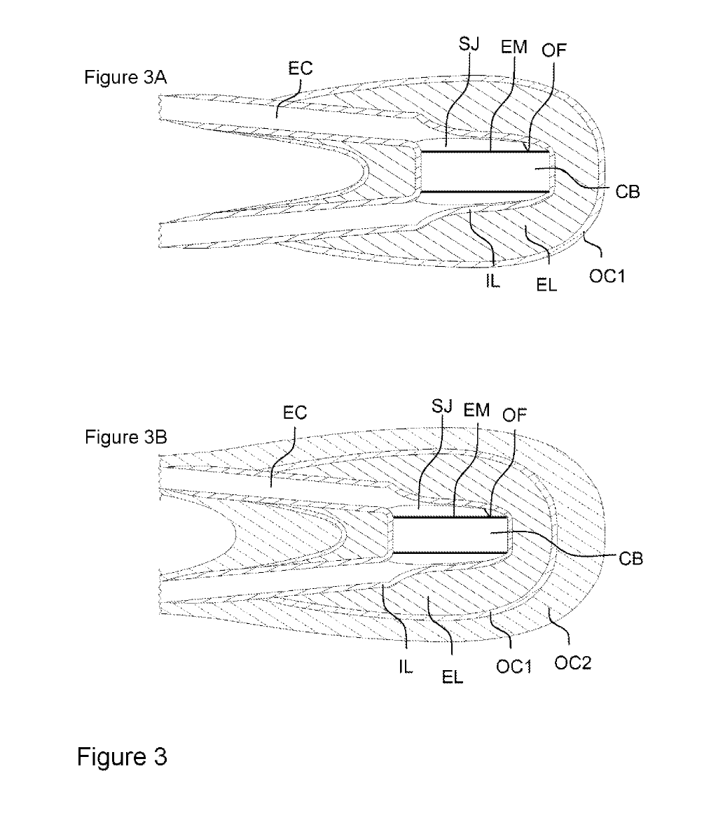

FIG. 3A shows an example of an NTC minisensor per FIG. 1 in which a first further protective layer (OC1) is additionally arranged outside on the outer protective layer (EL). In this case, the encapsulation of the component consists of a total of three protective layers. FIG. 3B shows a further variant of the component, in which a first further protective layer (OC1) and a second further protective layer (OC2) outside on the first further protective layer are arranged outside on the outer protective layer (EL). In this example, the second further protective layer (OC2) equates to an additional outer protective layer (EL). In FIG. 3C, a third further protective layer (OC3) is additionally arranged outside on the second further protective layer (OC2) on the component. It can easily be seen that these protective layer arrangements make it possible to realize components particularly well protected against penetration of surrounding media to the ceramic main body.

### Example 1

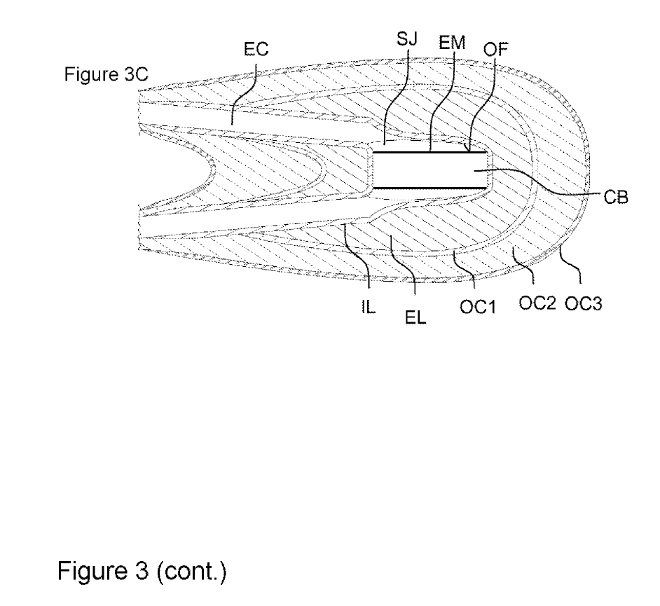

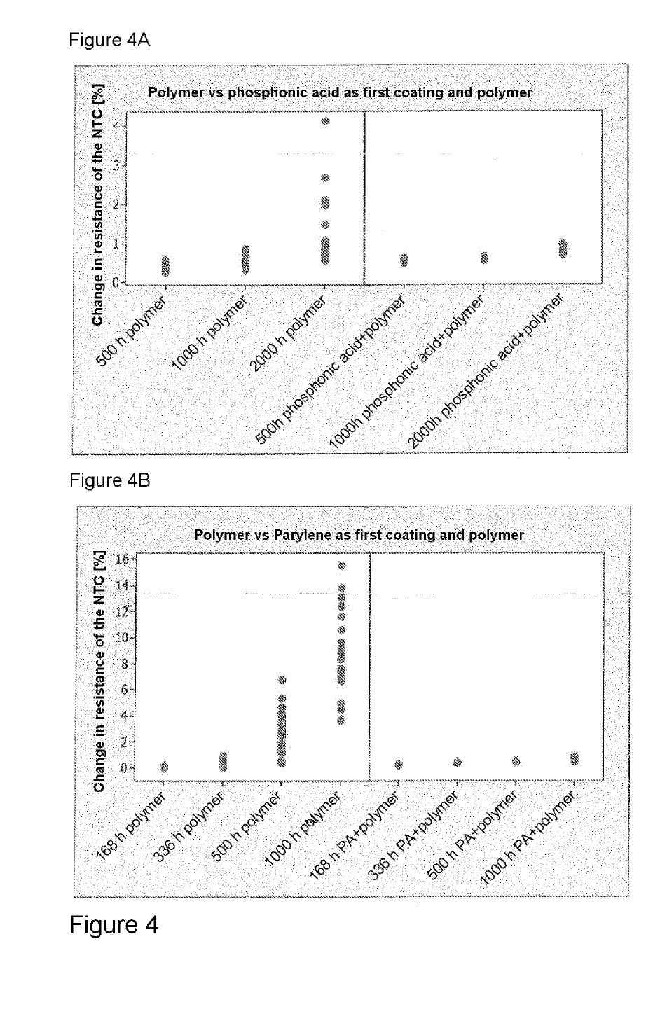

An NTC minisensor built up as described in FIGS. 1A to 1C has an inner protective layer composed of phosphonates and an outer protective layer composed of epoxy resin. The inner protective layer was produced from 1H,1H′,2H,2H′-perfluorooctyl-1-phosphonic acid in alcoholic solution in a dipping process. The outer protective layer was produced from 1-component epoxy resin, likewise in a dipping process. The ceramic main body consists of an MnCoFe system and has the dimensions 1.1×1.8×0.4 mm. Ag metallizations were used as metallizations on two opposite exterior sides of the ceramic main body. The component has a specific nominal resistance R25 of 2100Ω and a B value of 3570 K. Another ceramic component having the same specifications but only one encapsulation formed by a conventional epoxy resin coating serves as comparative object. To examine and compare the stability of the resistance parameters of the two components during use, the NTC minisensors were stored in water at 80° C. for a period of 2000 hours, with the specific nominal resistance of components being measured after 500, 1000 and 2000 hours and the resistance change compared to the nominal resistance before storage in water being calculated. The results of this experiment are shown in FIG. 4A. The diagrams show the time-dependent change in resistance of the NTC minisensor having a conventional epoxy resin coating (left-hand side) and having an inner protective layer composed of phosphonates and an outer protective layer composed of epoxy resin (right-hand side). The number of tests was in each case n=15. It can clearly be seen that a component encapsulated has a change in resistance of less than 1% even after storage in water at 80° C. for 2000 hours. At the same time, a small scatter in the resistance parameters within the test group having the encapsulation is observed, which makes the particular reliability of the ceramic components in use clear. On the other hand, the ceramic component having conventional encapsulation displays significant changes in resistance of up to 4%.

### Example 2

An NTC minisensor is built up as per the arrangement shown in FIGS. 1A to 1C. An inner protective layer composed of Parylene and an outer protective layer composed of epoxy resin is used for encapsulating the component. The inner protective layer was produced from Parylene-D by CVD. The outer protective layer was produced from 2-component epoxy resin in a dipping process. The ceramic main body has the dimensions 1.1×1.8×0.25 mm and consists of an MnNi system. Ag metallizations were used as metallizations on two opposite exterior sides of the ceramic main body. The component has a specific nominal resistance R25 of 3300Ω and a B value of 3988 K. The stability of the NTC minisensor encapsulated under use conditions was tested by storage in water at 80° C. FIG. 4B shows the time-dependent change in resistance of the NTC minisensor (right-hand side) compared to that of an NTC minisensor having a conventional epoxy resin coating in graph form (number of tests n=15 in each case). Measurement of the resistance parameters after 168 hours, 336 hours, 500 hours and 1000 hours in the NTC minisensor having an inner protective layer composed of Parylene and an outer protective layer composed of epoxy resin shows a change in resistance of not more than 1% compared to the initial resistance even after storage in water for 1000 hours. On the other hand, storage in water of the conventional component leads, even after 500 hours, to a significant change in resistance of up to about 7% with at the same time a large scatter in the resistance, and this increases further to up to about 16% after storage in water for 1000 hours.

Both examples thus show particularly clearly that the encapsulation of the NTC minisensors made it possible to produce ceramic components which display improved stability and reliability in respect of their specific electrical parameters compared to conventional components under use conditions.

Our components and methods are not limited to the examples presented here. Further variations, first and foremost with respect to the number and relative arrangement of the protective layers relative to one another and also with respect to the protective layer materials used and also the materials of the ceramic main body, the metallization and the electric inlet lead, are possible.

1-16. (canceled)

17. A ceramic component comprising:
a ceramic main body having at least one metalization on at least one exterior surface of the main body and at least one electric inlet lead in electrical contact with the metalization, and
an inner protective layer and an outer protective layer that encapsulates the component,
wherein the inner protective layer comprises at least one material selected from the group consisting of phosphonates (SAMP), silanes, Parylenes and combinations thereof, and
the inner protective layer
a) contains at least first functional groups via which covalent chemical bonding to at least the ceramic main body is effected and/or
b) has been deposited by chemical vapor deposition.

18. The ceramic component according to claim 17, wherein the inner protective layer is arranged on the ceramic main body, and the metalization and at least the part of the electric inlet lead adjoin the metalization.

19. The ceramic component according to claim 17, wherein covalent chemical bonding to the metalization and the electric inlet lead is additionally effected via the first functional groups.

20. The ceramic component according to claim 17, further comprising having an intermediate layer arranged between the inner protective layer and the outer protective layer.

21. The ceramic component according to claim 17, wherein the inner protective layer additionally contains second functional groups via which covalent chemical bonding to the outer protective layer and/or, if present, to the intermediate layer is effected.

22. The ceramic component according to claim 20, wherein the intermediate layer contains third functional groups via which covalent chemical bonding to the outer protective layer is effected.

23. The ceramic component according to claim 17, wherein the outer protective layer comprises at least one material selected from the group consisting of epoxy resins, polyurethanes, silicone elastomers and combinations thereof.

24. The ceramic component according to claim 19, wherein the intermediate coating comprises at least one material selected from the group consisting of Parylenes, silanes, phosphonates (SAMP) and combinations thereof.

25. The ceramic component according to claim 17, further comprising further protective layers arranged on the outer protective layer.

26. The ceramic component according to claim 17 configured as NTC resistor.

27. A method of producing a ceramic component according to claim 17, comprising:
A) providing the ceramic main body having the metalization on at least one exterior surface of the main body and the electric inlet lead in electrical contact with the metalization,
B) producing the inner protective layer, and
C) producing the outer protective layer on top of the inner protective layer.

28. The method according to claim 27, wherein the intermediate layer is produced on top of the inner protective layer in a further step B2) after step B) and before step C).

29. The method according to claim 27, wherein the inner protective layer is produced by chemical vapor deposition in step B).

30. The method according to claim 28, wherein the intermediate layer is produced by chemical vapor deposition in step B2).

31. The method according to claim 27, further comprising carrying out a plasma treatment in a further step B3) before step C).

32. The ceramic component according to claim 18, wherein covalent chemical bonding to the metalization and the electric inlet lead is additionally effected via the first functional groups.

33. The ceramic component according to claim 21, wherein the intermediate layer contains third functional groups via which covalent chemical bonding to the outer protective layer is effected.

34. The method according to claim 28, wherein the inner protective layer is produced by chemical vapor deposition in step B).

35. The method according to claim 29, wherein the intermediate layer is produced by chemical vapor deposition in step B2).
